(19) United States
(12) Patent Application Publication
(10) Pub. No.: US 2009/0102298 A1
(43) Pub. Date: Apr. 23, 2009

(54) Cooling housing for an electric device

(75) Inventors: Satish D. Savant, Peoria, IL (US); David M. Fee, Groveland, IL (US)

Correspondence Address: Caterpillar Inc.;Intellectual Property Dept., AH 9510, 100 N.E. Adams Street, PEORIA, IL, 61629-9510, US

(73) Assignee: Caterpillar Inc., Peoria, IL (US)

(21) Appl. No.: 11/975,612

(22) Filed: Oct. 19, 2007

(51) Int. Cl. H02K 9/00; H05K 7/20

(52) U.S. Cl. 310/52; 361/701

(57) ABSTRACT

A fluid-cooled electric device such as a generator, alternator or motor is provided with a housing that includes an outer surface defining an exterior of the device and an inner surface that defines a housing cavity with a longitudinal axis, and which may have an end wall enclosing one end of the housing cavity wherein the end wall is continuous with the inner surface. Integral to the housing is a helical cooling conduit, which may have a rectangular configuration, disposed along the axis between the inner and outer surfaces of the housing.

### TECHNICAL FIELD

This disclosure relates generally to an electric device such as a motor, generator or alternator, and more specifically, to a liquid cooling arrangement for such devices that includes a helical conduit integral to the housing thereof.

### BACKGROUND

Switched Reluctance (SR) electric devices such as, for example, motors and generators, may be used to generate mechanical power in response to an electrical input or to generate electrical power in response to a mechanical input. During operation, magnetic, resistive, and mechanical losses within such motors and generators cause a build up of heat, which may be dissipated to avoid malfunction and/or failure of the device. Moreover, one of the limitations on the power output of electric generators may be the capacity of the device to dissipate this heat. Accordingly, most of these device include some form of cooling system.

One example of a liquid cooled generator is depicted in FIG. 9. The generator 300, generally includes a rotor assembly 302 including a rotor shaft 304 with steel laminations 306. Surrounding the rotor assembly 302 is stator assembly 308, which includes a plurality of stator coils 310. Rotor 302 is configured for rotation about axis 312 within stator 308 for generation of electrical power in a conventional manner.

The stator 308 and rotor 302 are disposed within a cavity 314 defined by a generator housing including a front housing 316, middle housing 318, and rear housing 320, middle housing 318 including an inner surface 322. Fitted against inner surface 322 is a cooling sleeve 324 having a series of grooves 326 forming a cooling passage when outer surface 327 of sleeve 324 is mated against inner surface 322. O-rings 328 are positioned in the sleeve surrounding the grooves 326 to prevent leakage of coolant. The sleeve includes a radially extending flange 330 that is positioned against middle housing 318 end wall 332, the flange 330 being positioned between front housing 316 and middle housing 318. An upper axial lubricant/cooling bore 340 passes through the front housing 316, flange 330, middle housing 318, and rear housing 320, sealed by O-rings 334. Similarly, a lower lubricant/cooling sump 336 is sealed by O-rings 338 between the flange 330, front 316 and middle 318 housings.

The addition of a separate sleeve or other conduit forming member, along with the various sealing elements, increases both the number of parts required and production costs. More importantly, however, is that the seals may be compromised, resulting in leakage of coolant into the generator cavity or into the environment. This may result in lower cooling efficiency and potential damage to the generator components.

The present disclosure is directed to overcoming one or more of the problems set forth above.

### SUMMARY OF THE INVENTION

In one aspect, the present disclosure provides a fluid-cooled housing for an electric device having an outer surface and an inner surface that defines, at least in part, a housing cavity having a longitudinal axis. Continuous with the inner surface is an end wall that substantially encloses the housing cavity at a first end thereof. A helical conduit is integrated within the housing between the outer and inner surfaces thereof, along the axis.

In another aspect, provided is a fluid-cooled electric device having a housing including an outer surface that defines an exterior of the generator and an inner surface that defines a housing cavity having a longitudinal axis. A helical conduit is integrated within the housing between the outer and inner surfaces along the axis. The device may also include a rotor having a rotor shaft operatively connected to a power source for rotation thereof, and a stator including a stator coil substantially surrounding the rotor and positioned within the housing adjacent the inner surface thereof.

These and other aspects and advantages of the present disclosure will become apparent to those skilled in the art upon reading the following detailed description in connection with the drawings and appended claims.

### BRIEF DESCRIPTION OF THE DRAWINGS

FIG. 1 is a perspective view of an electric device in accordance with one embodiment of the present disclosure;

FIG. 2 is a perspective view of a rear housing of the device of FIG. 1;

FIG. 3 is a side, cross-sectional view of the device of FIG. 1;

FIG. 4 is an enlarged portion of the cross-section of FIG. 3;

FIG. 5 is a perspective view of a helical cooling conduit in accordance with one embodiment of the present disclosure;

FIGS. 6 is a cross-sectional view of an electric device in accordance with another embodiment of the present disclosure;

FIG. 7 is a perspective view of a helical cooling conduit in accordance with another embodiment of the present disclosure;

FIG. 8 is an enlarged, cross-sectional view of the helical cooling conduit of FIG. 6;

FIG. 9 is an illustration of a prior art liquid-cooled generator.

### DETAILED DESCRIPTION

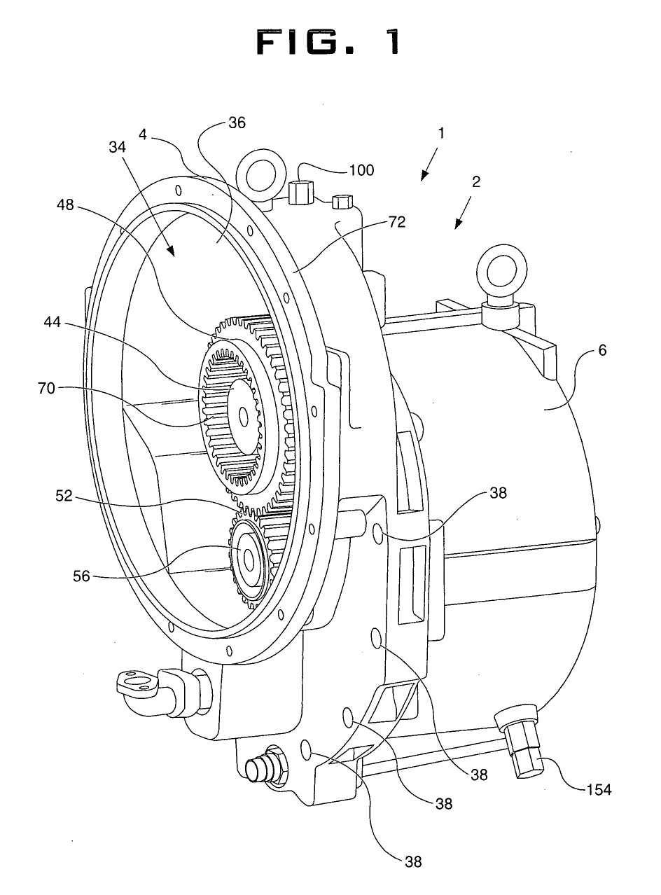

Referring to FIG. 1, shown is a rotary electric device 1, such as a generator, motor or alternator, particularly a switched reluctance electric device. Such devices are typically employed in connection with various machines to generate electric power or to convert electrical power to mechanical output. For example, such devices may be employed as a portion of a mobile machine such as, for example, a dozer, motorgrader, off-highway truck, excavator, loader or the like. It is also contemplated that the electric device may form a portion of a stationary unit, such as a generator set, pump or similar machines.

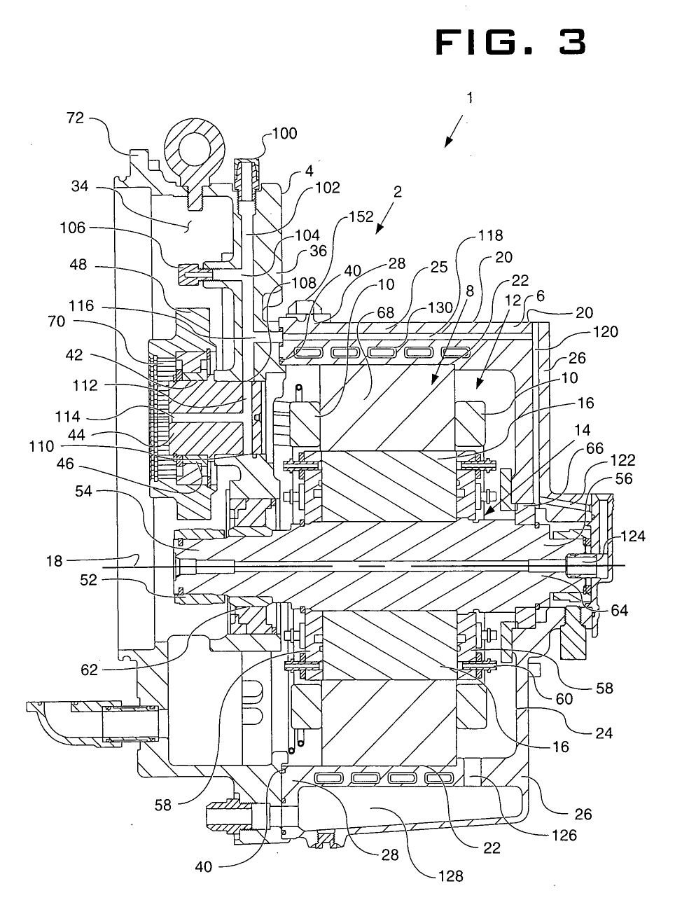

FIG. 3 is a cross-sectional view of the electric device 1 of FIG. 1. The device 1 generally includes a housing 2 that may consist of a front housing 4 and a rear housing 6, the housing 2 containing a stator assembly 8 having a stator coil 10. The stator assembly 8 is disposed within housing cavity 12 at least partially surrounding a rotor assembly 14 having a steel lamination 16, the rotor assembly 14 being operatively connected to a power source (not shown) for rotation about axis 18, thereby generating electrical power in a conventional manner.

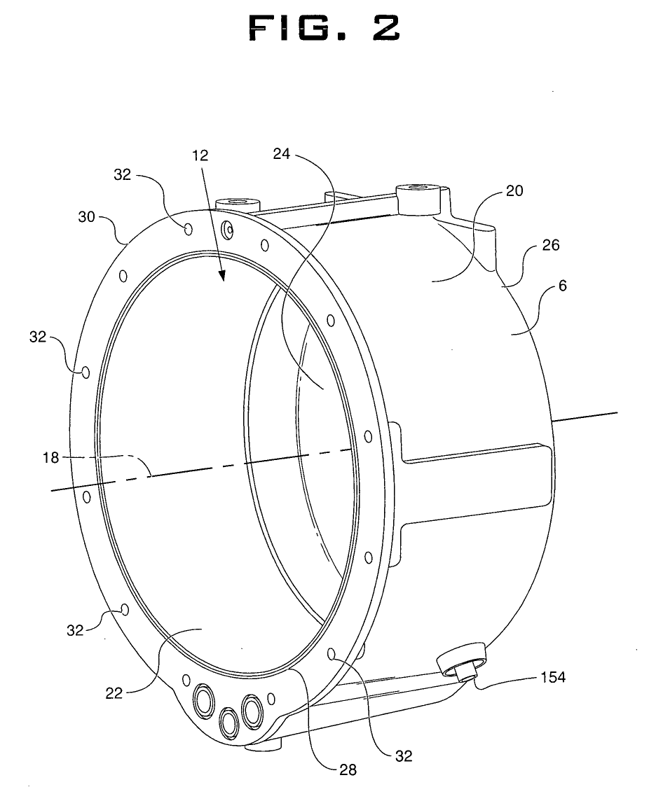

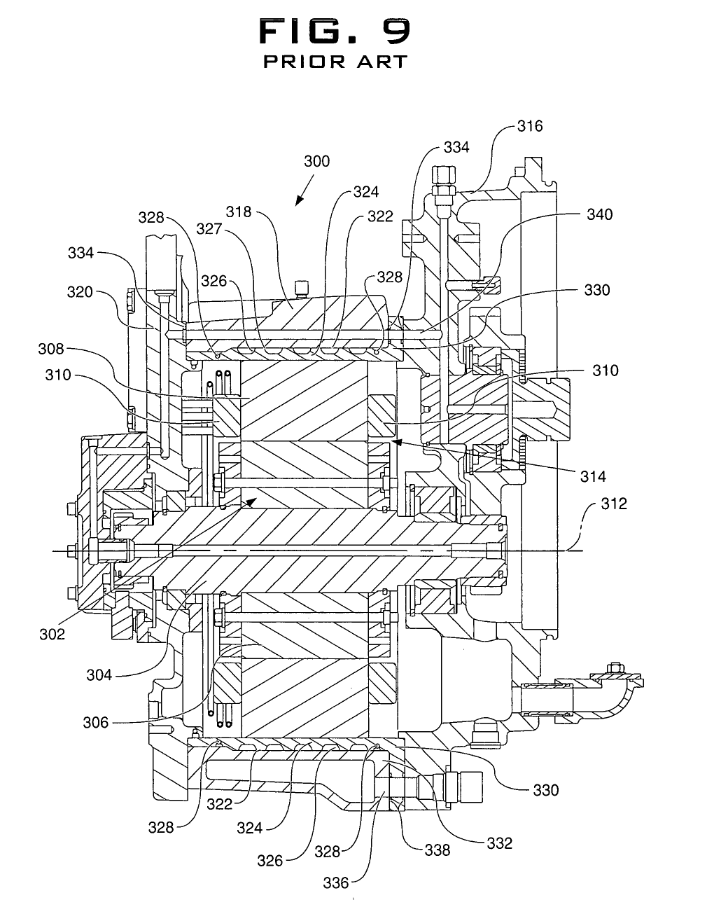

Referring to FIGS. 2-3, rear housing 6 may be generally cylindrical, having an outer surface 20 and an inner surface 22 defining inner cavity 12 which is disposed about axis 18. Enclosing one end 26 of the housing cavity 12 is rear wall 24 that is continuous with axial portion 25, and inner surface 22, of the housing. “Continuous” refers to the fact that the components are unitary, formed of a single, cast piece. However, in an alternative embodiment, the rear wall 24 (or a rear portion of the housing 2) may be formed of a separate component (for example, see prior art FIG. 9). Extending radially from a front end 28 of rear housing 6 is a generally annular flange 30 having a series of circumferentially disposed, spaced holes 32 for connection of the rear housing 6 to the front housing 4.

Front housing 4 defines the forward end of housing cavity 12, and also at least partially defines a gear cavity 34. Front housing 4 includes a radially extending wall 36 that includes a series of holes 38 which are aligned with the holes 32 of rear housing 6 for securing the two together. O-ring 40 acts as a sealing member between the rear 6 and front housing 4.

Wall 36 includes a bore 42 for supporting a gear shaft 44 that supports a roller bearing 46 and wheel gear 48 disposed coaxially about the shaft 42 for rotation thereon. The wheel gear 48 is configured to engage pinion gear 52 through a splined connection to a front end 54 of rotor shaft 56.

Rotor assembly 14 generally includes rotor shaft 56, including pinion gear 52, and a steel lamination 16 coaxial with the rotor shaft 56. The steel lamination 16 may, for example, be fastened to the rotor shaft 56 by interference fit, welding, threaded fastening, chemical bonding, or any other appropriate manner. The lamination 16 is positioned between a pair of opposed circular end plates 58, which include a series of circumferentially disposed balancing studs 60, employed for balancing the rotor assembly 14. The rotor assembly 14 is disposed along axis 18, supported at front end 54 for rotational movement by a roller bearing assembly 62, and at rear end 64 by a ball bearing assembly 66.

At least partially surrounding the rotor assembly 14 in a coaxial orientation is stator assembly 8, including a stator body 68 supporting coaxially aligned stator coils 10. The stator body 68 is held by friction fit against the inner surface 22 of rear housing 6.

In operation, a power source (not shown), such as a diesel or gasoline powered engine, may be operatively coupled to wheel gear 48 through an input shaft (not shown) that is configured to mate with inner splines 70. In one embodiment (not shown), a flywheel casing is connected to annular flange 72 at the front portion of front housing 4, the flywheel casing supporting a flywheel connected for rotation to the power source. The flywheel may be connected through a clutch assembly to the input shaft for rotation thereof. Thus, rotational power may be transferred from the power source through the input shaft and the wheel gear 48 to drive rotation of the rotor assembly 14, thereby generating electrical power. The rotor assembly 14 may be connected to a power source in any number of configurations known to those of skill in the art. For example, the input shaft may be coaxially aligned with the rotor shaft 56, or non-coaxially aligned via parallel axis gears (as shown), drive chains, belts, etc.

Referring to FIG. 3, lubricant input 100 is connected to a radially extending conduit 102 within wall 36. Disposed along conduit 102 is a first t-junction 104 which fluidly connects to a sprayer 106 having a nozzle (not shown) that is directed to deliver lubricant at the pinion gear 52 and wheel gear 48 within gear cavity 34. Lubricant also continues along conduit 102, which ends at an opening 108 above an annular groove 110 of cylindrical shaft 44. One or more openings (not shown) disposed in the groove 110 allows lubricant to flow via a radial passage 112 and axial passage 114 to the bearing 46, wheel gear 48, inner splines 70, and into the gear cavity 34. Lubricant may also flow from conduit 102 through t-junction 116 to axial upper passage 118 of rear housing 6, which extends from front end 28 to rear end 26 thereof. At rear end 26, axial upper passage 118 turns into radial rear wall passage 120 that directs lubricant to ball bearing assembly 66, and along angled passage 122 to the central rotor lubricant passage 124 which extends axially through the rotor shaft 56 into the gear cavity 34. One or more radial passages (not shown) are fluidly connected to central rotor passage 124 that deliver lubricant outwardly to lubricate the various parts within housing cavity 12. Lubricant that is directed into either the gear cavity 34 or housing cavity 12 ultimately drains through bottom passage 126 to sump 128.

The above-described lubricant/cooling circuit may be fluidly connected to one or more lubricant pumps and a heat exchanger as known in the art, and may be part of a larger system that pumps lubricant through a variety of machine components in addition to electric device 1.

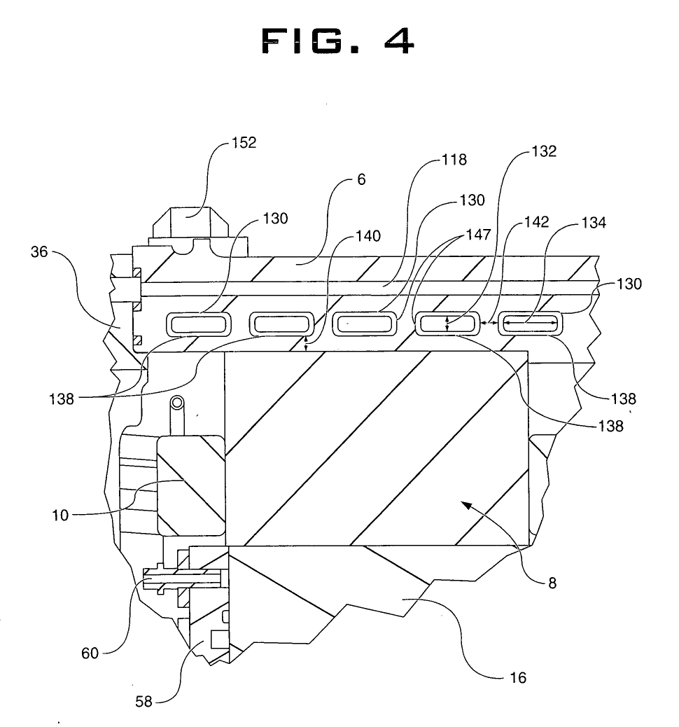

In one embodiment, the electric device 1 includes, as part of the overall cooling strategy for the device, a fluid cooling system that includes generally a helical conduit 130 that is integrated into the rear housing 6. For example, as shown in FIGS. 3-4, the rear housing 6 includes a helical conduit 130 having a substantially rectangular cross-section with a first, radial dimension 132 and a second, elongated, axial dimension 134, the helical conduit 130 being disposed coaxially along axis 18. By integrating the cooling conduit 130 into the housing 6, the device limits the number of necessary components, and eliminates leakage that may occur at the various seals necessary in conventional cooling arrangements.

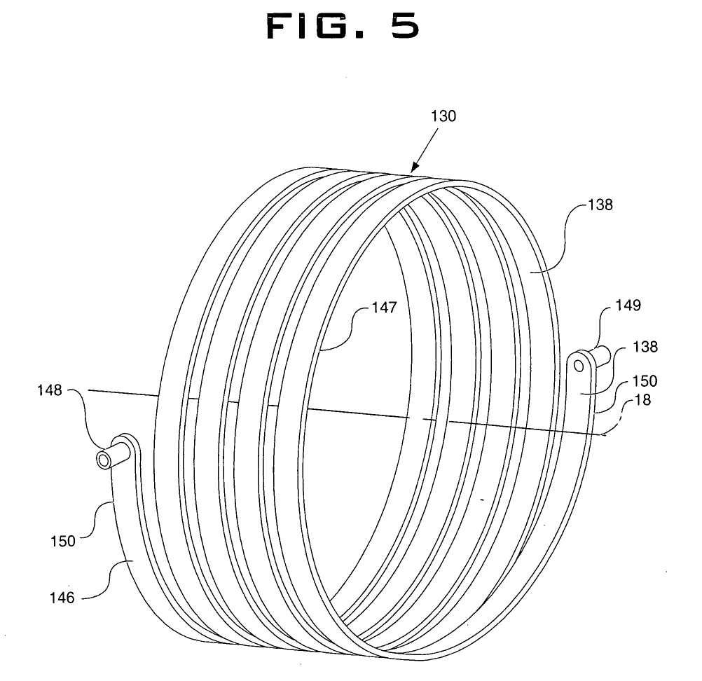

Referring to FIG. 5, shown is an exemplary helical conduit 130, having four and one half helical turns, a pitch of 40 mm, and a distance of 180 mm from end to end. However, one of skill in the art would readily appreciate that the specifications, including, without limitation, the length of the helix, number of turns, pitch, distance between coils, conduit wall thickness, and cross-sectional dimensions may be altered to a fit a variety of applications, depending on, for example, the size, weight and cooling requirements of any specific generator. Moreover, the helical coil does not need to be uniform with respect to any of these characteristics. For example, the pitch, cross-sectional dimension, and even the diameter of individual coils may vary. For example, in one embodiment, the helical conduit 130 may be a conical helix (not shown), wherein each successive turn has a decreasing diameter.

In one embodiment, the conduit 130 may be formed of cast or extruded steel, aluminum, copper, or other suitable metal material, including various alloys. One consideration will be selecting a material that will withstand the desired manufacturing process. In one embodiment, the housing is formed via metal casting, typically of cast aluminum. The conduit 130 will typically be set within the housing mold, and the molten aluminum poured to surround the conduit 130. Thus, the helical conduit 130 becomes an integral part of the rear housing 130. The term “integral” as used herein, means that the conduit 130 is fully enclosed, at least in part, within a unitary housing component, as opposed to being positioned between two or more components where leakage could occur. As a result of this process, however, it may be advantageous to select a conduit material that will have a higher melting temperature than the housing material. For example, in one embodiment, the housing will be aluminum cast, while the conduit will be made of steel.

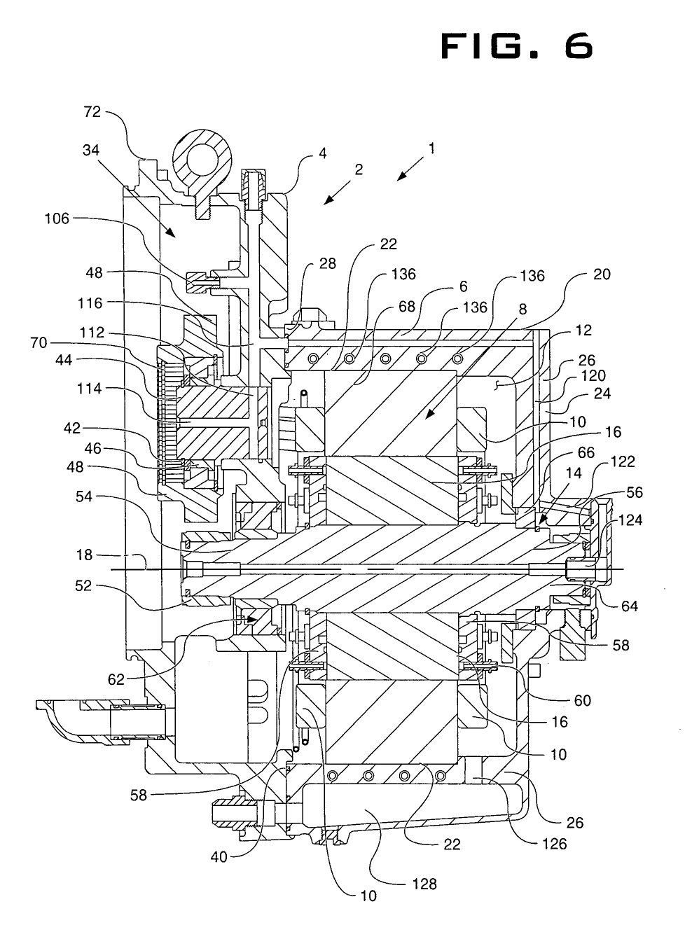

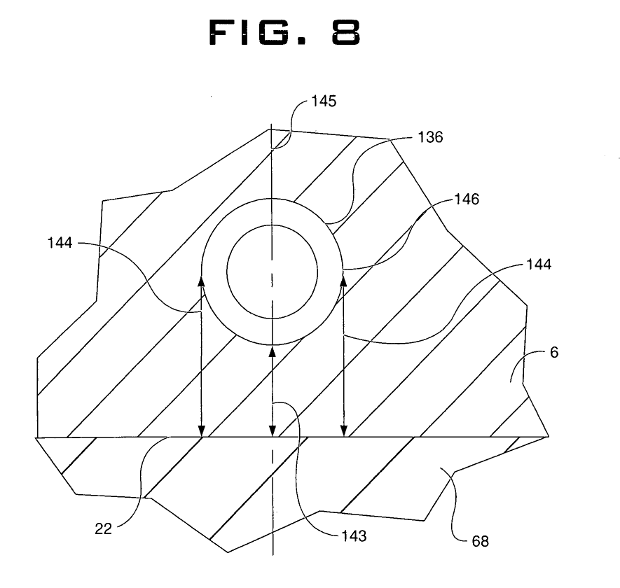

As discussed above, in one embodiment, shown in FIGS. 3-5, the conduit 130 has a rectangular cross-section, elongated axially. However, a variety of other cross-sectional dimensions may be employed. For example, in another embodiment, depicted in FIGS. 6-8, the helical conduit 136 may be cylindrical with a circular cross-section. However, the rectangular cross-section may be advantageous for a number of reasons. First, as shown in FIG. 4, the rectangular cross-section may provide a greater surface area along an inner surface 138, at a constant distance 140 from inner housing surface 22, which may facilitate heat exchange. In contrast, the circular cross-section of conduit 136 (FIG. 8) has a distance 143 from the outer surface 146 of the conduit to inner surface 22 of the rear housing 6 that increases to second distances 144 moving laterally from center line 145.

In addition, the rectangular configuration may have certain advantages in the manufacturing process due to the substantially uniform distance 142 between the side walls 147 of adjacent coils. In the case of cylindrical conduit 136, the varying distance between coils may be susceptible to the formation of voids between the conduits, and hence may require a larger spacing between coils to reduce any radial thermal differential during the solidification of casting.

As illustrated in the cylindrical and rectangular examples of FIGS. 3 and 5, the helical conduits 130, 136 are integral to the rear housing 6 in that the coils themselves are completely enclosed therein. In another embodiment (not shown), the helical conduits 130, 136 may be substantially, but not completely enclosed, with a portion of the conduits 130, 136 exposed to either the inner housing cavity 12, or to the external environment outside the housing. For example, inner surfaces 138 of the conduit 130 may be coextensive with inner wall 22 of the housing.

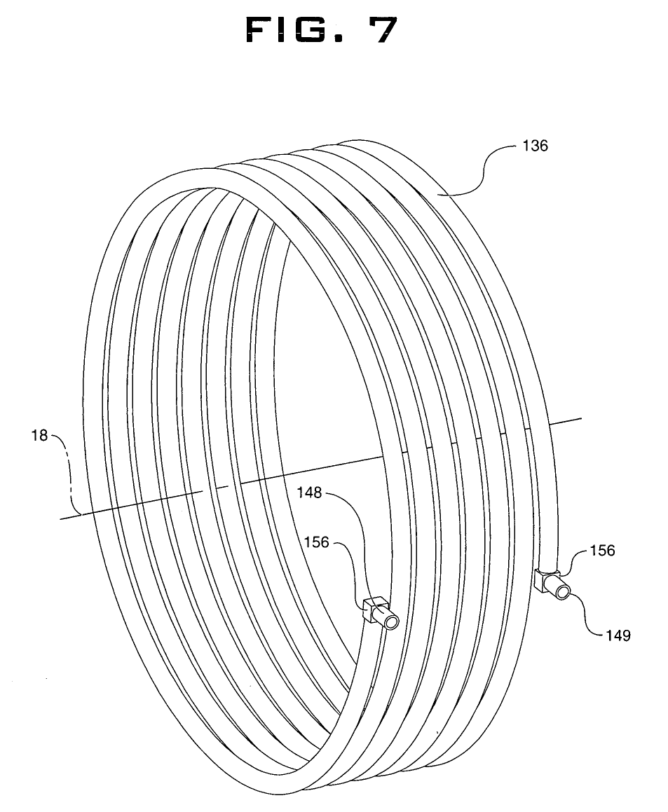

Referring to FIG. 5, the helical conduit 130 includes an inner surface 138 and an outer surface 146. At either end 150 of the conduit 130, there is provided a connection tube 148, 149 extending outwardly from the outer surface 146. The tubes 148, 149 may be welded to the conduit 130, and serve as inlet and outlet connections. The inlet 152, as shown in FIGS. 3 and 4 may be positioned gravitationally above the outlet 154 (FIGS. 1-2), with either or both being provided with a threaded connector. In an alternative embodiment, shown in FIG. 7, the helical conduit 136 may have end in a complete turn (seven shown), with the tubes 148, 149 being extending outwardly from junction boxes 156, and axially aligned on the same side of the generator housing 2.

In operation, a cooling system may include a pump (not shown) which is fluidly connected to inlet 152 to provide a circulating coolant, such as water, an ethylene glycol solution, or the like. The system may also include a heat exchanger to remove heat from the coolant prior to circulating the coolant back through the device 1. A pump may be dedicated to providing coolant for the electric device 1, or the system may also be fluidly connected to other components, such as an engine fluid jacket or oil heat exchanger (not shown).

While aspects of the present disclosure have been particularly shown and described with reference to the embodiments above, it will be understood by those skilled in the art that various additional embodiments may be contemplated without departing from the spirit and scope of the present disclosure. For example, the cooling system may include two or more helical conduits 132 disposed within the same or separate housing elements of a generator 1. More specifically, in one embodiment (not shown), the housing 2 may include a first housing body having a first helical coil and a second housing body having a second helical coil which are either connected to each other, or are separately supplied with coolant. This may be particularly useful in the assembly of large electric devices, or where there is a need to separately cool a specific area of the housing. In yet another embodiment, two or more coils may be integrated within the same housing body, coils being disposed in an overlapping or alternating configuration. Again, the coils may be fluidly connected or separately supplied with coolant for increased cooling capacity.

These and other embodiments should be understood to fall within the scope of the present invention as determined based upon the claims below and any equivalents thereof.

### INDUSTRIAL APPLICABILITY

The housing designs of the present disclosure may be used in connection with various electric devices to provide fluid-cooling with less components, and at a potentially lower cost that conventional designs. Moreover, the fact that there are no internal seals between the coolant passages and the interior of the device may result in improved performance and lifespan of the device by preventing leakage that may occur when such seals fail. In particular, the housings may be used in connection with switched reluctance electric devices such as, for example, motors, alternators and generators.

Such electric devices may be used in connection with any machine that requires the generation of electrical power from a mechanical input, or mechanical power from an electrical input. This may include mobile machines such as construction, passenger and recreational vehicles, trucks, and watercraft. These devices may also be employed in mobile industrial machinery, such as that used in mining, construction, farming, transportation, or any other industry known in the art. This may include earth moving machines such as dozers, wheel loaders, excavators, dump trucks, backhoes, motorgraders and the like. In particular, the disclosed SR electric devices may find applicability in the drive systems of such vehicles. It should be recognized that a wide variety of applications, mobile and stationary, may fall within the scope of the present disclosure.

Other aspects, objects, and advantages of the present disclosure can be obtained from a study of the drawings, disclosure and the appended claims.

What is claimed is:

1. A fluid-cooled housing for an electric device, comprising:
an outer surface and an inner surface, the inner surface defining, at least in part, a housing cavity having a longitudinal axis;
an end wall continuous with the inner surface, thereby substantially enclosing the housing cavity at a first end thereof;
a helical conduit integrated within the housing between the outer and inner surfaces along the axis.

2. The housing of claim 1, wherein the housing includes a second end having a radially extending circumferential flange.

3. The housing of claim 1, wherein the helical conduit has a rectangular cross-section.

4. The housing of claim 3, wherein the rectangular cross-section is defined by a first, elongated dimension disposed substantially parallel to the axis.

5. The housing of claim 4, wherein the conduit further comprises an outer surface and a first end, a tube fluidly connected to the conduit in the proximity of the conduit end and extending substantially perpendicular to the outer surface of the conduit.

6. The housing of claim 5, wherein the tube extends beyond the outer surface of the housing.

7. The housing of claim 1, wherein the conduit has a first end and a second end that extend outward from the outer surface of the housing.

8. The housing of claim 7, wherein the first end is positioned above the second end relative to an upper portion of the housing.

9. The housing of claim 1, wherein the conduit is constructed of steel, aluminum, or copper.

10. The housing of claim 1, wherein the housing includes a lubricant bore extending axially from a first end to a second end of the housing.

11. A fluid-cooled electric device, comprising:
a housing including an outer surface defining, at least in part, an exterior of the electric device, and an inner surface, the inner surface defining, at least in part, a housing cavity having a longitudinal axis;
a helical conduit integrated within the housing between the outer and inner surfaces along the axis.

12. The electric device of claim 11, wherein the helical conduit has a rectangular cross-section.

13. The electric device of claim 12, wherein the rectangular cross-section is defined by a first, elongated dimension disposed substantially parallel to the axis.

14. The electric device of claim 12, wherein the conduit further comprises an outer surface and a first end, a tube fluidly connected to the conduit in the proximity of the conduit end and extending substantially perpendicular to the outer surface of the conduit.

15. The electric device of claim 14, wherein the tube extends beyond the outer surface of the housing.

16. The electric device of claim 11, wherein the conduit has a first end and a second end that extend outward from the outer surface of the housing.

17. The electric device of claim 16, wherein the first end is positioned above the second end relative to an upper portion of the electric device.

18. A fluid-cooled switched reluctance electric device, comprising:
a housing including an outer surface defining, at least in part, the exterior of the generator, and an inner surface, the inner surface defining, at least in part, a housing cavity having a longitudinal axis, a helical conduit integrated within the housing between the outer and inner surfaces along the axis;
a rotor having a rotor shaft operatively connected to a power source for rotation thereof;
a stator including a stator coil surrounding said rotor and positioned within said housing adjacent the inner surface.

19. The electric device of claim 18, wherein the helical conduit has a rectangular cross-section.

20. The electric device of claim 18, wherein the housing cavity is substantially cylindrical, the housing further comprising a first end having a radially disposed end wall continuous with the inner surface and substantially enclosing the housing cavity at the first end.
